(19) United States
(12) Patent Application Publication
(10) Pub. No.: US 2017/0067147 A1
(43) Pub. Date: Mar. 9, 2017

(54) Heating Device for Evaporation Machine and Evaporation Machine

(71) Applicants: BOE Technology Group Co., Ltd., Beijing (CN); Hefei Xinsheng Optoelectronics Technology Co., Ltd., Anhui (CN)

(72) Inventors: Qinghua Zou, Beijing (CN); Jianwei Yu, Beijing (CN)

(21) Appl. No.: 15/088,841

(22) Filed: Apr. 1, 2016

(30) Foreign Application Priority Data
Sep. 8, 2015 (CN) 201510568427.6

(51) Int. Cl. C23C 14/50

(52) U.S. Cl. CPC C23C 14/50

(57) ABSTRACT

A heating device for an evaporation machine and an evaporation machine are disclosed. The heating device includes: a heating chamber, the heating chamber is provided with a cavity and an opening, the opening being arranged on a top of the heating chamber; an inner box, which is arranged in the cavity of the heating chamber and removable from the cavity of the heating chamber; and a nozzle component, which comprises a nozzle, wherein the nozzle is arranged on the top of the inner box, an inlet of the nozzle is connected to an interior of the inner box, and an outlet of the nozzle passes through the opening on the top of the heating chamber.

This application claims priority to and the benefit of Chinese Patent Application No. 201510568427.6 filed on Sep. 8, 2015, which application is incorporated herein in its entirety.

### FIELD OF THE ART

Embodiments of the invention relate to the technical area of evaporation technologies, more particularly, to a heating device for an evaporation machine and an evaporation machine.

### BACKGROUND

In order to form an organic functional layer of an Organic Light-Emitting Diode (OLED), an evaporation machine is generally employed to heat and evaporate organic materials so that gaseous organic materials are deposited on a base substrate homogeneously. The conventional evaporation machines are classified into dot-source evaporation machines and linear-source evaporation machine, based on the type of heating source in use.

A linear heating device typically comprises a heating chamber, a nozzle and a crucible. A heating component and a cooling device and the like are fixed to the heating chamber, the nozzle is fixed to the top of the heating chamber, and the crucible is arranged inside the heating chamber. When an organic material placed in the crucible is heated and evaporated, a part of gaseous organic material is sprayed from an outlet of the nozzle to form an organic functional layer of the OLED, and another part of organic material is deposited on internal walls of the heating chamber, or adhered to the outlet of the nozzle and the like. The deposited organic material accumulates with time, which severely compromises the heating effect of the heating device. Therefore, the heating device must be cleaned and maintained regularly. Currently, there are mainly two cleaning maintenance methods of the heating device. The first method is referred to as completely disassembling maintenance, that is, the crucible is taken away from the heating chamber, and the heating component and cooling device are disassembled from the heating chamber; after that, the interior of the heating chamber and various components are cleaned or replaced, respectively. The second method is the so-called dry burning maintenance, that is, the organic material is volatilized at a relatively high rate under a temperature higher than a normal evaporating temperature so as to clean those organic material deposited on the interior surface of the heating chamber and the nozzle.

However, when completely disassembling maintenance method is employed, the process of disassembling the heating component and cooling device from the heating chamber and subsequent assembly process is complicated and takes a relatively long time, which therefore reduces a maintenance efficiency of the heating device. When dry burning maintenance method is employed, the organic material is prone to be pyrolyzed and carbonized due to the high temperature, making it impossible to remove the residual organic material in this way again. Moreover, the gas with a high temperature sprayed from the outlet of the nozzle may be deposited on the components around the outlet of the nozzle, which accelerates the aging of the components, thereby increasing a replacement frequency of the components. Moreover, if the organic material is a melting type material, the organic material will melt, flow and drip, thereby increasing the difficulty of maintenance.

### SUMMARY

A first aspect of the invention provides a heating device for an evaporation machine, comprising: a heating chamber, the heating chamber is provided with a cavity and an opening, the opening being arranged on a top of the heating chamber; an inner box, which is arranged in the cavity of the heating chamber and removable from the cavity of the heating chamber; and a nozzle component, which comprises a nozzle, wherein the nozzle is arranged on the top of the inner box, an inlet of the nozzle is connected to an interior of the inner box, and an outlet of the nozzle passes through the opening on the top of the heating chamber.

Another aspect of the invention further provides an evaporation machine, comprising the above heating device for an evaporation machine.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 schematically illustrates a heating device for an evaporation machine in accordance with an embodiment of the invention;

FIG. 2 schematically illustrates a nozzle component of a heating device for an evaporation machine in accordance with an embodiment of the invention;

FIG. 3 schematically illustrates a cross section of an inner box of a heating device for an evaporation machine in accordance with an embodiment of the invention;

FIG. 4 schematically illustrates an inner box of a heating device for an evaporation machine in accordance with an embodiment of the invention;

FIG. 5 schematically illustrates a front view of a heating device for an evaporation machine in accordance with an embodiment of the invention; and

FIG. 6 schematically illustrates a side view of a heating device for an evaporation machine in accordance with an embodiment of the invention.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at least one. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

An embodiment of the invention provides a heating device for an evaporation machine and an evaporation machine. The heating device can be partly disassembled and cleaned, which avoids the complicated disassembly and assembly caused by a completely disassembly operation, thereby saving the maintenance time, increasing the maintenance efficiency. Moreover, it also avoids a dry burning clean process, reducing a replacement frequency of components around the outlet of a nozzle, as well as the difficulty of maintenance.

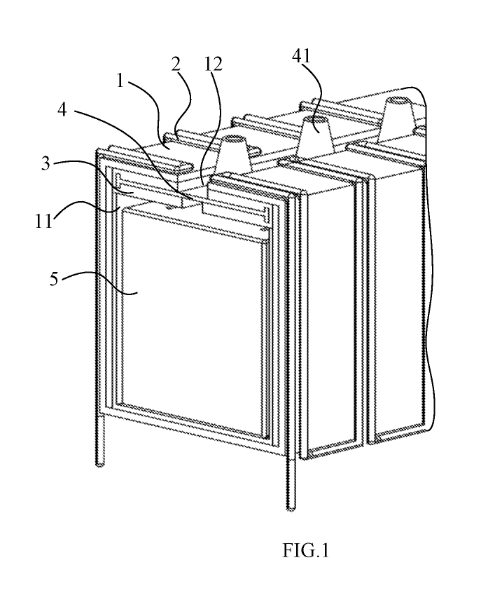

FIG. 1 schematically illustrates a heating device for an evaporation machine in accordance with an embodiment of the invention. The heating device comprises a heating chamber 1, and a cavity 11 is arranged inside the heating chamber 1. A heating component 2 is arranged outside the heating chamber 1, the heating component 2 can heat the cavity 11. An opening 12 is arranged on the top of the heating chamber 1. The heating device further comprises an inner box 3. The inner box 3 is arranged in the cavity 11 of the heating chamber 1, and is made of a heat conductive material. Moreover, the inner box 3 is removable from the cavity 11 of the heating chamber 1. The heating device further comprises a nozzle component 4, which includes a nozzle 41. The nozzle 41 is arranged on the top of the inner box 3, an inlet of the nozzle 41 is connected to the interior of the inner box 3, and an end of the nozzle 41 having an outlet thereof passes through the opening 12 on the top of the heating chamber 1. A crucible 5 is arranged in the inner box 3 and the crucible 5 is removable from the interior of the inner box 3.

Due to the interior of the inner box 3 being connected to the interior of the crucible 5 and the inlet of the nozzle 41 respectively and an end of the nozzle 41 having the outlet passing through the opening 12 on the top of the heating chamber 1, the gaseous organic material evaporated by the crucible 5 first enters into the interior of the inner box 3, then enters into the nozzle 41 through the inlet of the nozzle 41, and then is sprayed from the outlet of the nozzle 41. The gaseous organic material will not flow through a gap between the heating chamber 1 and the inner box 3, which avoids the pollution of the cavity 11 caused by the organic material flowing into the gap, thereby omitting the cleaning operation on the heating chamber land the complicated disassembly and assembly operations. Moreover, it also reduces the replacement frequency of components around the outlet of the nozzle and the difficulty of maintenance. The nozzle 41 included in the nozzle component 4 is arranged on the top of the inner box 3, the crucible 5 is arranged in the interior of the inner box 3, the inner box 3 is removable from the cavity 11, and the crucible 5 is removable from the interior of the inner box 3. Due to the above configuration, when the heating device is being maintained, merely the inner box 3, the nozzle component 4 and the crucible 5 need to be removed from the heating chamber 1. Then, respective components are disassembled, and replaced or cleaned as required. Comparing with the conventional technology, the above partial disassembly method realizes a simpler assembly and disassembly operation of the heating device for an evaporation machine which is helpful for the cleaning maintenance, thereby saving the maintenance time and increasing the maintenance efficiency.

As an example, in order to further reduce the maintenance time and cost, the nozzle component 4 is designed to be detachable from the top wall of the inner box 3, as illustrated in FIG. 1. When one of the nozzle component 4 and the inner box 3 fails to work or needs to be cleaned, it is possible to replace or clean the faulty one.

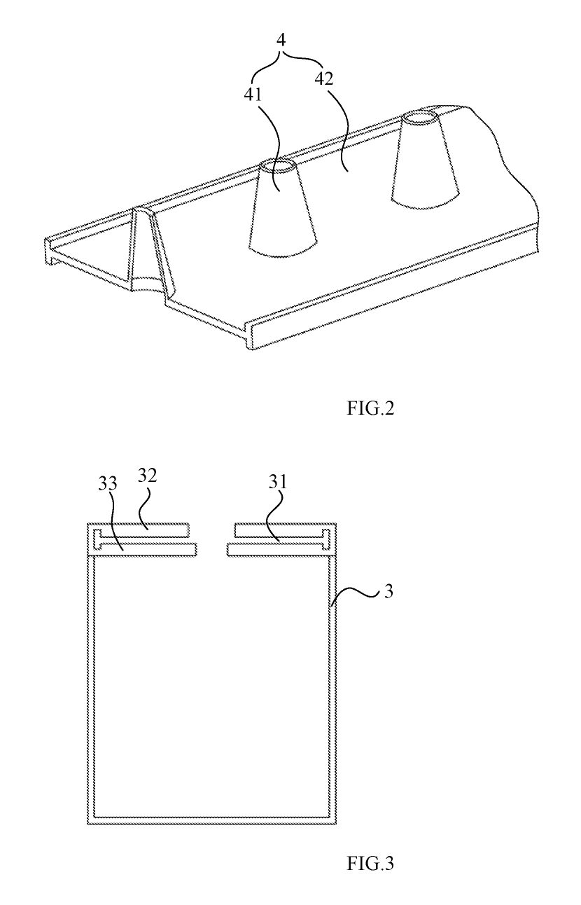

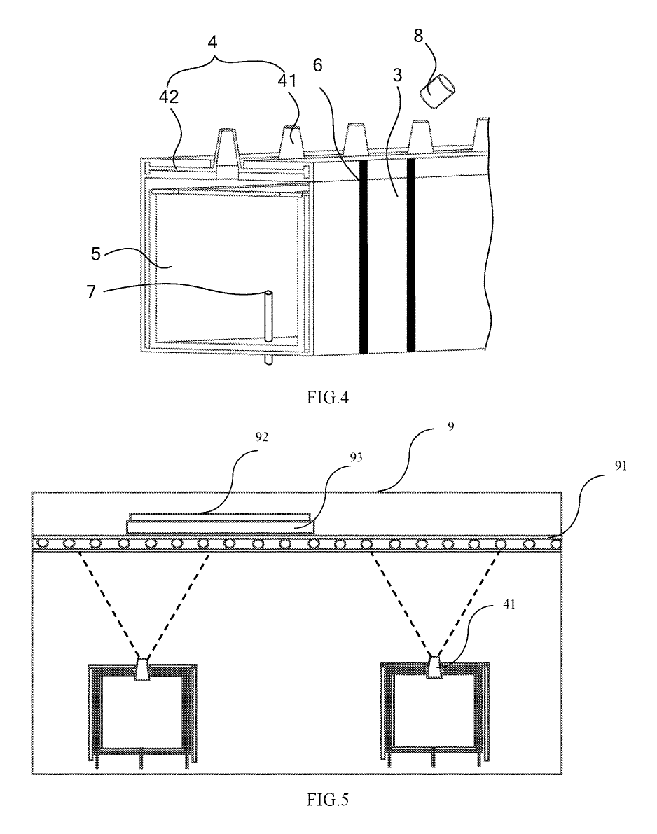

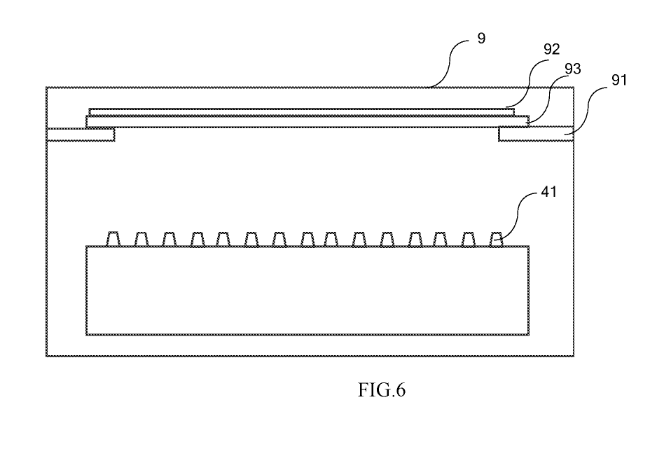

As an example, the nozzle component 4 has a configuration as illustrated in FIG. 2, that is, the nozzle component 4 further comprises a fixing plate 42 and the nozzle 41 is disposed on the fixing plate 42. As an example, the inner box 3 has a configuration as illustrated in FIG. 3. The top wall of the inner box 3 is provided with a slot 31 and the fixing plate 42 is inserted into the slot 31. A connecting way between the nozzle component 4 and the top wall of the inner box 3 may be designed as illustrated in FIG. 4, wherein the nozzle component 4 can be pulled out from the slot 31 of the fixing plate 42 during a cleaning process, thus realizing the separation of the nozzle component 4 and the inner box 3 which allows the nozzle component 4 and the inner box 3 to be replaced or cleaned separately as required, thereby reducing the maintenance time and the maintenance cost.

As an example, the nozzle 41 is fixed to the fixing plate 42 by using a connector such as a bolt, a pin, a rivet or the like. Alternatively, it may also design the nozzle 41 and the fixing plate 42 as an integrally formed structure as illustrated in FIG. 2. When the former solution is employed, the gaseous material may leak from the connection gap between the nozzle 41 and the fixing plate 42. Alternatively, the nozzle 41 and the fixing plate 42 is designed as an integrally formed structure so that there is no connection gap between the nozzle 41 and the fixing plate 42, thereby realizing an effective sealing between the nozzle 41 and the fixing plate 42.

A cross section of the fixing plate 42 is for example “H” shaped as illustrated in FIG. 2.In this case, a cross section of the slot 31 is also “H” shaped as illustrated in FIG. 3, which allows the fixing plate 42 and the slot 31 to match with each other. Moreover, a “H” shaped cross section can extend a diffusion path of the organic material between the slot 31 and the fixing plate 42, thereby more effectively realizing the connection seal between the fixing plate 42 and the slot 31, and reducing the probability of the organic material flowing into the gap between the heating chamber 1 and the inner box 3.

In order to realize a linear heating effect of the heating device for an evaporation machine, the nozzle 41 is designed as for example to be plural and the plurality of nozzles 41 is fixed on the fixing plate 42, which allows the plurality of nozzles 41 and the fixing plate 42 to be connected together and can be detached from the inner box 3 as a whole.

As an example, the plurality of nozzles 41 are arranged along a straight line or a curved line. When the latter design is employed, the opening 12 on the top of the heating chamber 1 needs to be configured to have a relatively large width, that is, the width of the opening 12 is larger than that of the nozzles 41 corresponding to the opening 12, such that all the plurality of nozzles 41 arranged along a curved line can pass through the opening 12. However, when the opening 12 on the top of the heating chamber 1 has a relatively large width, the closeness of the heating chamber 1 may be affected. Alternatively, as an example, the plurality of nozzles 41 is arranged along a straight line, which allow the width of the opening 12 to be configured as the same as the width of the nozzles 41 corresponding to the opening 12, thus the width of the opening 12 is relatively small, thereby further increasing the closeness of the heating chamber 1, and the heating efficiency of the heating component 2 to the cavity 11.

As an example, the inner box 3 can be fabricated as illustrated in FIG. 3, that is, the top wall of the inner box 3 is a dual-layer structure which comprises an upper plate 32 and a lower plate 33. A slot 31 is formed between the upper plate 32 and the lower plate 33, so that the nozzle component 4 can be fixed on the inner box 3 by inserting the fixing plate 42 into the slot 31. The lower plate 33 is provided with a plurality of lower openings in positions corresponding to the nozzles 41, the lower openings are connected with the inlets of the plurality of nozzles 41, respectively. It may also be configured as illustrated in FIG. 3, that is, one opening is connected with all the inlets of the plurality of nozzles 41. Comparing with the latter solution, the former solution can further increase the closeness of the inner box 3 and reduce the amount of the gaseous organic material flowing into the gap between the heating chamber 1 and the inner box 3. Therefore, the lower opening which is connected to the inlet of the nozzles 41 is arranged in a position of the lower plate 33 corresponding to the nozzle 41. The upper opening which allows the nozzle 41 to pass through is arranged in a position of the upper plate 32 corresponding to the nozzle 41. As an example, the width of the upper opening equals to the maximum width of the nozzle 41 (for example, because the cross-section of the nozzle 41 has a shape of isosceles trapezoid as illustrated in FIG. 4, the maximum width of the nozzle 41 is the length of the bottom side of the isosceles trapezoid), thereby reducing the width of the upper opening, increasing the closeness of the connection between the inner box and the fixing plate, and allowing the nozzle component 4 to contact to the inner box 3 tightly.

A size of the lower opening may be larger than that of the inlet of the nozzle 41, or may be smaller than that of the inlet of the nozzle 41, or may be equal to that of the inlet of the nozzle 41. When the first solution is employed, that is, the size of the lower opening is larger than that of the inlet of the nozzle 41, the gaseous organic material goes into the inlet of the nozzle 41 through the lower opening, and some of the gaseous organic material is blocked by the surface of component in the connecting position, causing the gas to radially diffuse and goes into the connection gap, thereby increasing the amount of gas going into the gap, which further increases the possibility of the gas going into the gap between the heating chamber 1 and the inner box 3 through that gap. When the second solution is employed, that is, the size of the lower opening is smaller than that of the inlet of the nozzle 41, the gaseous organic material goes into the inlet of the nozzle 41 through the lower opening and reduces the speed. The gas having a relatively low speed has a relatively large static pressure to the side wall of the inlet of the nozzle 41, causing more gas to enter the connection gap, which also increases the possibility of the gas going into the gap between the heating chamber 1 and the inner box 3 through that gap. Therefore, as an example, the shape and size of the lower opening are same as the shape and size of the inlet of the nozzle 41, so that the gaseous organic material goes into the inlet of the nozzle 41 through the lower opening without a change of flow rate, and the value of static pressure on the wall of lower opening is identical to the value of static pressure on the side wall of the inlet and the static pressure is relatively small, which reduces the amount of the gas going into the connecting gap. Moreover, having no block in the connecting position reduces the possibility of the gas being radially diffused, thereby reducing the amount of the gas going into the connecting gap, which further reduces the possibility of the gas going into the gap between the heating chamber 1 and the inner box 3.

In order to increase the homogeneity of heating from the heating component 2 to the cavity 11, as illustrated in FIG. 1, the heating component 2 is for example a heating wire and the heating wire is wound on an exterior surface of the heating chamber 1, which allows the heat from the heating component 2 to be transmitted to the cavity 11 homogeneously through the whole exterior surface of the heating chamber 1. As the inner box 3 is made of a heat conductive material, the heat in the cavity 11 can be transmitted to the inner box 3 homogeneously, thereby realizing a homogeneous heating to the organic material in the crucible 5.

After the evaporation is finished and before the cleaning operation, it is possible to rapidly cool the heating device through a cooling device to save the waiting time and increase efficiency. As an example, a cooling pipe 6 is wound on an exterior surface of the heating chamber 1 as illustrated in FIG. 4, which rapidly cools the heating chamber 1. Moreover, during the evaporation operation, the cooling pipe 6 takes away the redundant heat outside of the heating chamber 1 so as to avoid the affection of the adjacent heating device. Moreover, the cooling pipe 6 further reflects the heat inside the heating chamber 1, thereby accumulating the heat inside the interior of the heating chamber 1 to heat the organic material.

As an example, in order to detect the heating temperature of the organic material, a temperature sensor 7 is arranged inside the cavity 11 of the heating chamber 1 as illustrated in FIG. 4, and the temperature sensor 7 detects the temperature in the cavity 11. As the inner box 3 is made of a heat conductive material, the temperature of the interior of the inner box 3 is approximately equal to that of the cavity 11, that is, the temperature detected by the temperature sensor 7 is the heating temperature of the organic material in the inner box 3, thereby realizing the control of the heating temperature according to the detected temperature and allowing the heating temperature to be controlled in a reasonable scope.

When a constant heating time is given, an evaporating thickness depends on a flow rate of the vapor in the outlet of the nozzle 41. The larger is the flow rate of the vapor in the outlet of the nozzle 41, the thicker is the evaporating thickness. Thus, to control the evaporating thickness, the rate of the vapor at the outlet of the nozzle 41 is monitored. As an example, a vapor flow rate detection device is disposed at the outlet of the nozzle 41 as illustrated in FIG. 4 to monitor the flow rate of the vapor and control the evaporating thickness.

The embodiment of the invention further provides an evaporation machine comprising the heating device for an evaporation machine of any of above embodiments.

As the heating device used in the embodiment of the invention is the same with that of above embodiments, the two devices can solve same technical problems and achieve a same expecting result.

As an example, the evaporation machine further comprises a housing 9 and a transporting device 91 arranged in the housing 9 as illustrated in FIG. 6, wherein the heating device is arranged on the bottom of the housing 9, the transporting device 91 is arranged above the heating device and is configured to support a substrate 92, and the nozzle 41 and the substrate 92 are arranged as opposite to each other.

The transporting device 91 is for example a conveyer belt. When the substrate 92 is transported to a position opposite to the nozzle 41, the nozzle 41 sprays the gaseous organic material to allow the organic material adhered to the substrate 92, thereby realizing the evaporating operation. A mask plate 93 is for example arranged on the substrate.

What is described above is related to the illustrative embodiments of the disclosure only and not limitative to the scope of the disclosure; the scopes of the disclosure are defined by the accompanying claims.

The present application claims priority from Chinese Application No. 201510568427.6, filed on Sep. 8, 2015, the disclosure of which is incorporated herein by reference in its entirety.

What is claimed is:

1. A heating device for an evaporation machine, comprising:
a heating chamber which is provided with a cavity and an opening, the opening being arranged on a top of the heating chamber;
an inner box which is arranged in the cavity of the heating chamber and removable from the cavity of the heating chamber; and
a nozzle component comprising a nozzle, wherein the nozzle is arranged on the top of the inner box, an inlet of the nozzle is connected to an interior of the inner box, and an outlet of the nozzle passes through the opening on the top of the heating chamber.

2. The heating device of claim 1, wherein the nozzle component is detachably mounted to a top wall of the inner box.

3. The heating device of claim 2, wherein the nozzle component further comprises a fixing plate, the nozzle is connected to the fixing plate, a slot is arranged on the top wall of the inner box, and the fixing plate is inserted into the slot.

4. The heating device of claim 3, wherein a cross section of the fixing plate is “H” shaped and a cross section of the slot is “H” shaped.

5. The heating device of claim 3, wherein a number of the nozzle is plural, all the nozzles are fixed on the fixing plate.

6. The heating device of claim 5, wherein the plurality of nozzles are arranged along a straight line.

7. The heating device of claim 3, wherein the top wall of the inner box comprises an upper plate and a lower plate, the slot is formed between the upper plate and the lower plate, a lower opening is arranged on the lower plate in a position corresponding to the nozzle and is connected to the inlet of the nozzle, and an upper opening is arranged on the upper plate in a position corresponding to the nozzle and is configured to allow the nozzle to pass therethrough.

8. The heating device of claim 7, wherein a shape of the lower opening is same as a shape of the inlet of the nozzle.

9. The heating device of claim 8, wherein a size of the lower opening is same as a size of the inlet of the nozzle.

10. The heating device of claim 1, wherein a heating component is disposed outside the heating chamber to heat the cavity.

11. The heating device of claim 10, wherein the heating component is a heating wire and the heating wire is wound on an exterior surface of the heating chamber.

12. The heating device of claim 1, wherein a cooling pipe is wound on an exterior surface of the heating chamber.

13. The heating device of claim 1, wherein a temperature sensor is arranged inside the cavity of the heating chamber, and the temperature sensor is configured to detect a temperature of the inner box.

14. The heating device of claim 1, wherein a vapor flow rate detection device is disposed at the outlet of the nozzle.

15. The heating device of claim 1, wherein the inner box is made of a heat conductive material.

16. The heating device of claim 1, wherein a crucible is arranged in the inner box and the crucible is removable from the interior of the inner box.

17. An evaporation machine comprising the heating device for an evaporation machine of claim 1.

18. The evaporation machine of claim 17, further comprising: a housing and a transporting device arranged in the housing, wherein the heating device is arranged on the bottom of the chamber, the transporting device is arranged above the heating device and is configured to support a substrate, and the nozzle and the substrate are arranged as opposite to each other.
